(19) United States
(12) Patent Application Publication
(10) Pub. No.: US 2005/0258523 A1
(43) Pub. Date: Nov. 24, 2005

(54) Heat dissipation module for an electronic device

(75) Inventors: Sheng-Pin Su, Chung Li City (TW); Chun-Kun Yu, Tao Yuan City (TW)

Correspondence Address: TROXELL LAW OFFICE PLLC, 5205 LEESBURG PIKE, SUITE 1404, FALLS CHURCH, VA, 22041, US

(73) Assignee: EINS OE-TECH CO., LTD.

(21) Appl. No.: 10/846,498

(22) Filed: May 17, 2004

(51) Int. Cl. H01L 23/495

(52) U.S. Cl. 257/675

(57) ABSTRACT

A heat dissipation module is used for a high-power semiconductor laser device with an operation current below 2 amperes and has a housing, a plurality of air holes in side panels of the housing, an air outlet on a rear panel of the housing, and a heat dissipation module in the housing. The heat dissipation module has a heat-dissipating plate and a base placed beside the heat-dissipating plate. The base has a plurality of holes corresponding to a current controller, the current controller is arranged on one face of the heat-dissipating plate and near the air outlet, and the current controller has pins connected to holes on the base through insulating unit and wire. Therefore, the high-power semiconductor laser device can be operated at a stable temperature.

### FIELD OF THE INVENTION

The present invention relates to a heat dissipation module for an electronic device, and especially to a heat dissipation module for a high-power semiconductor laser device with an operation current below 2 amperes.

### BACKGROUND OF THE INVENTION

FIG. 1 shows a block diagram of a prior art high-power semiconductor laser device, which comprises a power unit 91, a semiconductor laser 92, a current controller 93 controlling the semiconductor laser 92, a cooling chip 94 and a cooling controller 95 for controlling the cooling chip 94. The thermal source in the high-power semiconductor laser device includes mainly the high-power semiconductor laser and a high-power element in the current controller 93, which may be soldered to a printed circuit board.

In the past, the heat dissipation module is generally designed to remove heat from the semiconductor laser and the heat from the high-power element in the cooling controller is seldom addressed.

FIG. 2 shows a schematic diagram of high-power semiconductor laser module with a heat-dissipating solution. The high-power semiconductor laser module comprises a housing 10, a resilient stage 15, a high-power semiconductor laser module 20, a mask 25, at least one heat-dissipating fan 30 and a voltage regulator 35. The resilient stage 15 is arranged on bottom of the housing 10 and has an insulating post 16 at front end thereof, an insulating spring 17 at rear end thereof. The high-power semiconductor laser module 20 has a heat-dissipating ring 23 around it and atop the resilient stage 15, and the mask 25 is arranged on panel of the housing 10. The heat-dissipating fan 30 includes a first fan installed inside the housing 10 and beside the heat-dissipating hole for drawing air or draining air, and a second fan at a standoff 18 in the housing and used for drawing air or draining air through holes 19. The voltage regulator 35 is arranged on inner bottom side of the housing 10 to provide stable electric power to the high-power semiconductor laser module 20 and the heat-dissipating fan 30.

However, the heat dissipation of the high-power semiconductor laser module 20 relies on the heat-dissipating ring 23, only. The heat-dissipating fan 30 provides a limited heat-dissipating effect because of the arrangement thereof. The above-mentioned arrangement does address the heat dissipation issue for the voltage regulator 35.

Therefore, it is desirable to provide a heat dissipation module for a high-power semiconductor laser device, which can remove heat both from the semiconductor laser and the high-power element in the current controller, whereby the high-power semiconductor laser device can be operated at a stable temperature.

### SUMMARY OF THE INVENTION

It is an object of the present invention to provide a heat dissipation module for a high-power semiconductor laser device with an operation current below 2 amperes.

It is another object of the present invention to provide a heat dissipation module for removing heat from the high-power element in the current controller.

To achieve above objects, the present invention provides a heat dissipation module for a high-power semiconductor laser device with an operation current below 2 amperes. The heat dissipation module comprises a housing, a plurality of air outlets in one side panel of the housing, and a heat dissipation module in the housing. The heat dissipation module has a heat-dissipating plate and a base placed beside the heat-dissipating plate. The base has a plurality of holes corresponding to a current controller. The current controller is arranged on one face of the heat-dissipating plate and near the air outlet, and the current controller has pins connected to holes on the base through insulating unit and wire.

The current controller is locked to the heat-dissipating plate through a mica plate, an insulating washer and a screwing element.

The insulating unit can be insulating sleeve.

The heat dissipation module for a high-power semiconductor laser device can further comprise a connection stage arranged corresponding to the holes on the base.

The pins of the current controller are connected to the connector through insulating unit and wire and the connector is connected to the connection stage.

The heat dissipation module for a high-power semiconductor laser device can further comprise a thermostat arranged on one side of the heat-dissipating plate.

### BRIEF DESCRIPTION OF DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a block diagram of a prior art high-power semiconductor laser device;

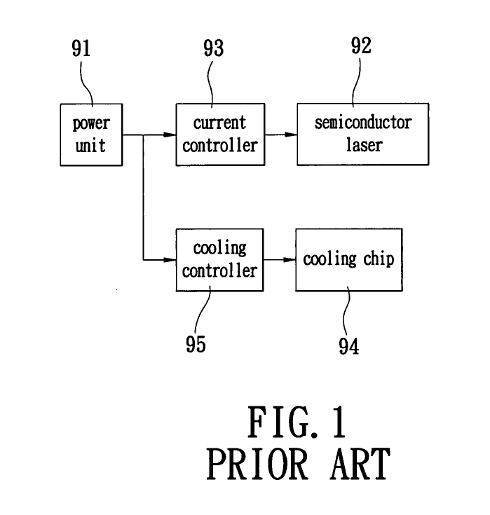

FIG. 2 shows a schematic diagram of high-power semiconductor laser module with heat-dissipating solution;

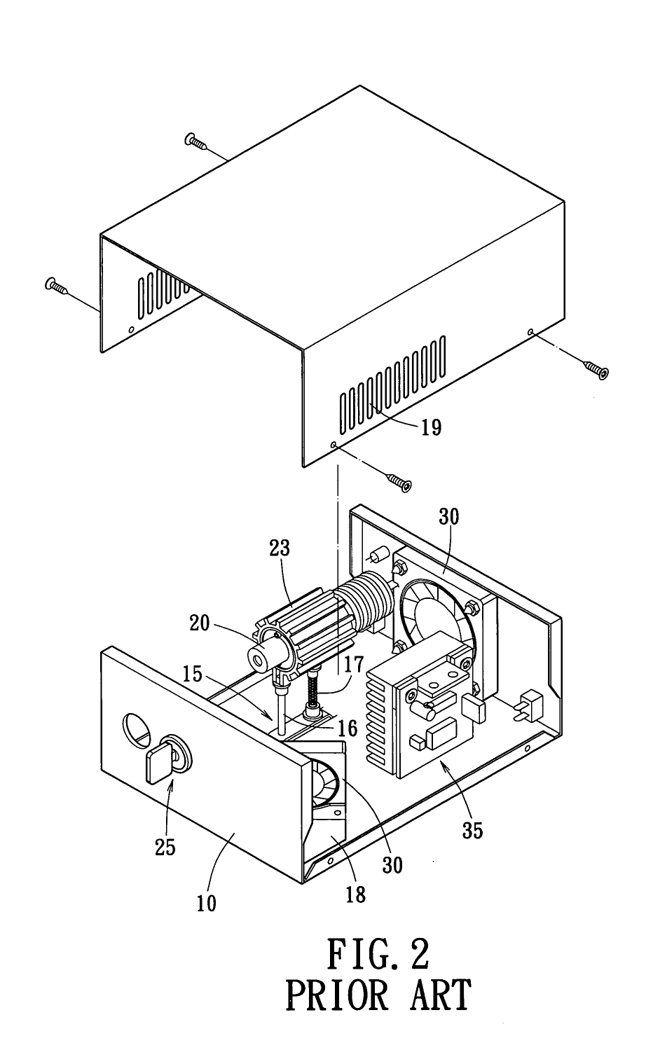

FIG. 3 shows an exploded view of the heat dissipation module for an electronic device according to the present invention;

FIG. 4 shows a schematic diagram of the heat dissipation module for an electronic device according to the present invention;

FIG. 5 shows that the current controller is assembled with the heat-dissipating module; and

FIG. 6 shows another preferred embodiment of the present invention.

### DETAILED DESCRIPTION OF THE INVENTION

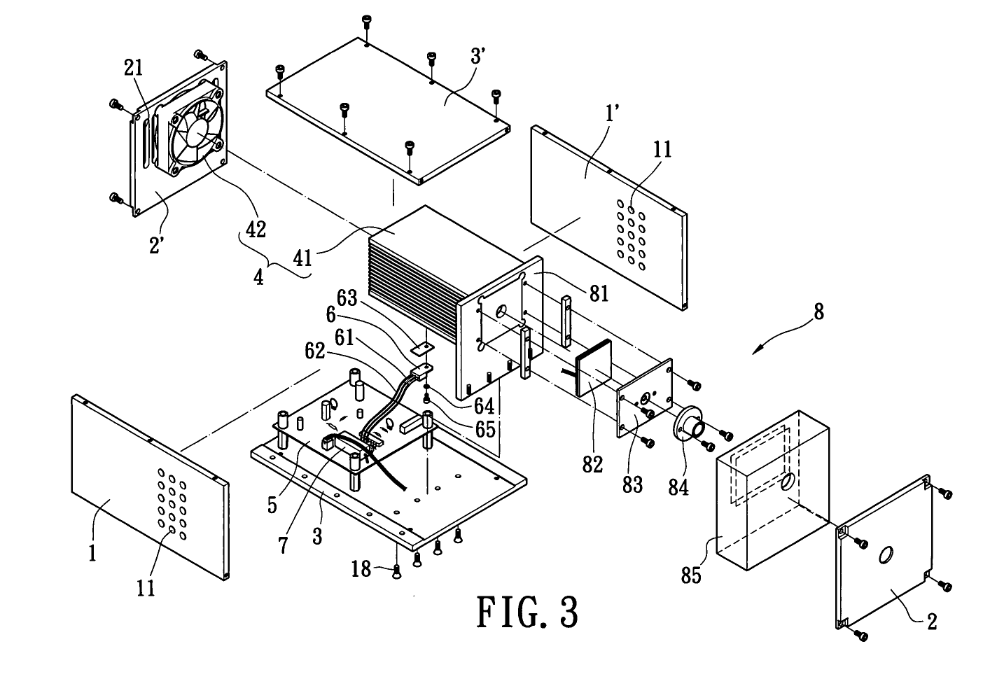

FIG. 3 shows an exploded view of the heat dissipation module for an electronic device according to the present invention. This heat dissipation module according to the present invention is used for a high-power semiconductor laser device with an operation current below 2 amperes. The high-power semiconductor laser device comprises a housing including two side panels 1 and 1′, a front panel 2, a rear panel 2′, a bottom panel 3 and a top panel 3′, a plurality of air holes 11 in the side panels 1 and 1′, an air outlet 21 on the rear panel 2′ and a heat dissipation module 4 in the housing. The heat dissipation module 4 comprises a heat-dissipating plate 41 and a fan 42. A thermostat 8 is arranged on one side of the heat-dissipating plate 41 and is composed of a metal baffle 81, a cooling chip 82, a metal retainer 83, a semiconductor light emitting module 84 and a thermal isolator 85. A base 5 is placed below the heat-dissipating plate 41 and a current controller 6 and a cement resistor 7 are placed on the base 5. The current controller 6 is arranged on a bottom face of the heat-dissipating plate 41 and near the air outlet 21. The pins of the current controller 6 are connected to holes in the base 5 through insulating sleeve 61 and wire 62.

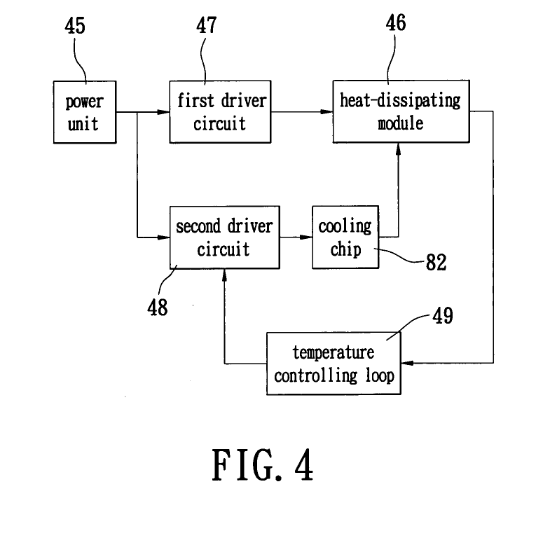

As shown in FIG. 4, the high-power semiconductor laser device comprises a power unit 45, a first driver circuit 47 for driving a heat dissipation module 46, a second driver circuit 48 for driving the cooling chip 82 and a temperature controlling loop 49 connected between the heat dissipation module 46 and the second driver circuit 48 for maintaining a constant temperature for the high-power semiconductor laser device.

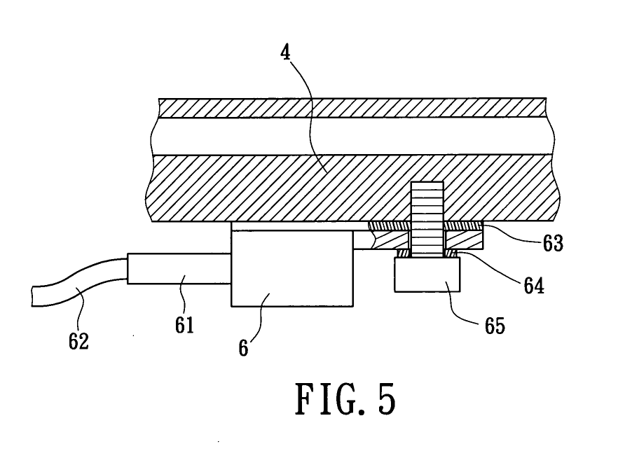

With reference to FIGS. 3 and 5, the current controller 6 is locked to the heat dissipation module 4 through a mica plate 63, an insulating washer 64 and a screwing element 65. The current controller 6 is a bipolar junction transistor (BJT).

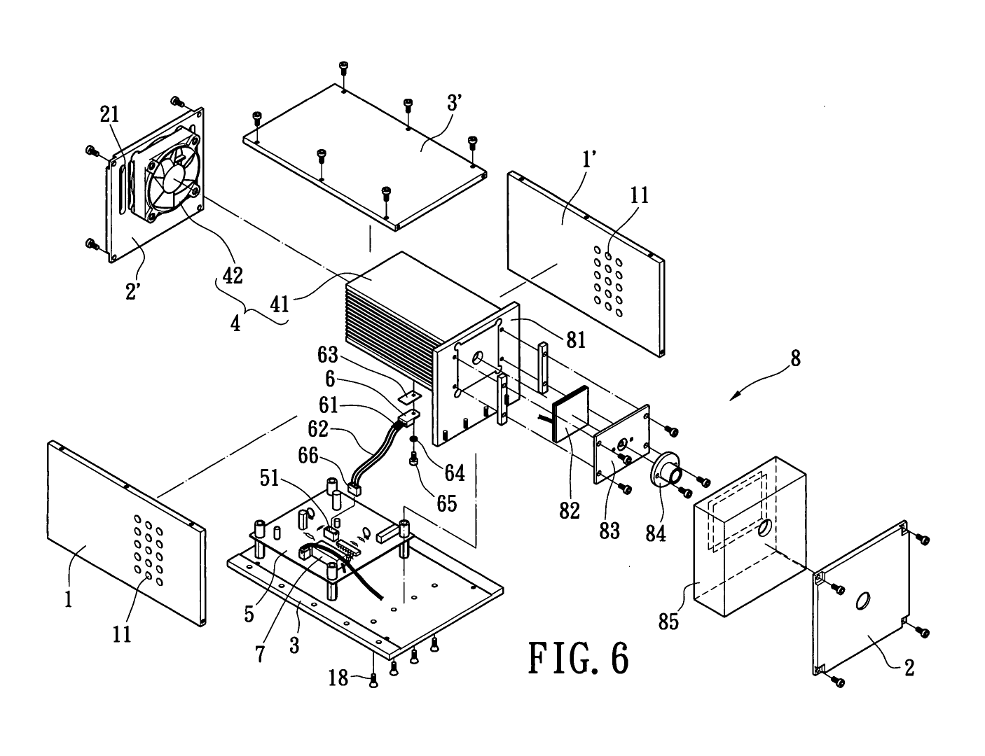

With reference to FIG. 6, the pins of the current controller 6 can be connected to a connection stage 51 of the base 5 through insulating sleeve 61, wire 62 and connector 66. The connection stage 51 corresponds to holes for current controller 6 on the base 5.

The heat generated by the current controller 6 can be dissipated through the heat-dissipating plate 41, the fan 42 and the air outlet 21. Therefore, the current controller 6 can be operated at a stable temperature.

To sum up, the heat dissipation module according to the present invention can provide environment of stable temperature for a high-power semiconductor laser device by removing heat from the high-power element in the current controller.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

1. A heat dissipation module for a high-power semiconductor laser device with an operation current below 2 amperes, comprising:
a housing, with a plurality of air outlets in one side panel of the housing; and
a heat dissipation module, the heat dissipation module located in the housing and having a heat-dissipating plate and a base placed beside the heat-dissipating plate, the base having a plurality of holes corresponding to a current controller, the current controller being arranged on one face of the heat-dissipating plate and near the air outlet, and the current controller having pins connected to holes in the base through insulating unit and wire.

2. The heat dissipation module for a high-power semiconductor laser device as in claim 1, wherein the current controller is locked to the heat-dissipating plate through a mica plate, an insulating washer and a screwing element.

3. The heat dissipation module for a high-power semiconductor laser device as in claim 1, wherein the insulating unit is an insulating sleeve.

4. The heat dissipation module for a high-power semiconductor laser device as in claim 1, wherein the current controller is a bipolar junction transistor (BJT).

5. The heat dissipation module for a high-power semiconductor laser device as in claim 1, further comprising a thermostat arranged on one side of the heat-dissipating plate.

6. A heat dissipation module for a high-power semiconductor laser device with an operation current below 2 amperes, comprising:
a housing, with a plurality of air outlets in one side panel of the housing; and
a heat dissipation module in the housing, the heat dissipation module having a heat-dissipating plate and a base placed beside the heat-dissipating plate, the base having a connection stage for connecting to a current controller, the current controller being arranged on one face of the heat-dissipating plate and near the air outlet, the current controller having pins connected to a connector through the insulating unit and wire, and the connector being connected to the connection stage on the base.

7. The heat dissipation module for a high-power semiconductor laser device as in claim 6, wherein the current controller is locked to the heat-dissipating plate through a mica plate, an insulating washer and a screwing element.

8. The heat dissipation module for a high-power semiconductor laser device as in claim 6, wherein the insulating unit is an insulating sleeve.

9. The heat dissipation module for a high-power semiconductor laser device as in claim 6, wherein the current controller is a bipolar junction transistor (BJT).

10. The heat dissipation module for a high-power semiconductor laser device as in claim 6, further comprising a thermostat arranged on one side of the heat-dissipating plate.
